(19) United States
(12) Patent Application Publication
(10) Pub. No.: US 2025/0379553 A1
(43) Pub. Date: Dec. 11, 2025

(54) OSCILLATOR MASTER BOARD, OSCILLATORS AND METHOD FOR MAKING THE SAME

(71) Applicant: AKER TECHNOLOGY CO., LTD., Taichung City (TW)

(72) Inventors: Ray-Hua Horng, Taichung City (TW); Yi-Lun Lin, Taichung City (TW)

(73) Assignee: AKER TECHNOLOGY CO., LTD., Taichung City (TW)

(21) Appl. No.: 19/223,532

(22) Filed: May 30, 2025

(30) Foreign Application Priority Data
Jun. 6, 2024 (TW) 113120965

(51) Int. Cl. H03H 3/04; H03H 9/05; H03H 9/13

(52) U.S. Cl. CPC H03H 3/04; H03H 9/0542; H03H 9/13; H03H 2003/0435

(57) ABSTRACT

An oscillator master board includes a frame, oscillators and connecting portions. The frame includes an outer frame and connecting frames that are disposed within the outer frame and that are connected to the outer frame. The connecting frames extend along a first direction and are spaced apart from each other along a second direction that intersects the first direction. The oscillators are spaced apart from each other. Each of the oscillators is disposed adjacent to a corresponding one of the connecting frames and includes an oscillator substrate, a top frame, a top electrode unit and a back electrode unit. The connecting portions are disposed to connect the oscillators to the connecting frames. Each of the oscillators is connected to the corresponding one of the connecting frames through at least a corresponding one of the connecting portions. A method for making the oscillator master board is also provided.

### CROSS-REFERENCE TO RELATED APPLICATION

This application claims priority to Taiwanese Invention patent application No. 113120965, filed on Jun. 6, 2024, the entire disclosure of which is incorporated by reference herein.

### FIELD

The disclosure relates to oscillators and a method for making the same, and more particularly to an oscillator master board for making oscillators, a method for making the oscillator master board, the oscillators, and a method for making the oscillators.

### BACKGROUND

Resonators, such as quartz oscillators, are components that utilize piezoelectric effect of quartz crystals to generate oscillation frequencies, and are often disposed in various electronic products (e.g., communication devices). A quartz oscillator typically includes a quartz substrate, a top electrode formed on a top surface of the quartz substrate, and a back electrode formed on a bottom surface of the quartz substrate. The back electrode extends from the bottom surface of the quartz substrate toward a peripheral surface to the top surface of the quartz substrate, so that the top electrode and the back electrode can be located on the same surface for external electrical connection. In order to enable the quartz oscillator to be applied to a high-frequency band, the quartz substrate must be thinned to a certain thickness (e.g., not greater than 30 μm) to achieve a required high-frequency oscillation band (e.g., an oscillation frequency greater than 90 MHz).

However, during manufacturing of the aforementioned high-frequency oscillator, the quartz substrate is too thin and prone to cracking, thereby adversely effecting production yields of the high-frequency oscillator. Therefore, how to alleviate the problems caused by thinning of the quartz substrate so as to enhance production yields of the high-frequency oscillator is an important task for those skilled in the art.

### SUMMARY

Therefore, an object of the disclosure is to provide an oscillator master board, a method for making the oscillator master board, oscillators, and a method for making the oscillators that can alleviate at least one of the drawbacks of the prior art.

According to a first aspect of the disclosure, the oscillator master board includes a frame, oscillators and connecting portions. The frame includes an outer frame and connecting frames that are disposed within the outer frame and that are connected to the outer frame. The connecting frames extend along a first direction and are spaced apart from each other along a second direction that intersects the first direction. The oscillators are spaced apart from each other. Each of the oscillators is disposed adjacent to a corresponding one of the connecting frames, and includes an oscillator substrate, a top frame, a top electrode unit and a back electrode unit. The oscillator substrate has an upper surface and a lower surface that are opposite to each other. The upper surface has a center portion and an outer edge portion that surrounds the center portion. The top frame is formed on the outer edge portion of the oscillator substrate. The top electrode unit includes a top electrode that is formed on the center portion. The back electrode unit includes a back electrode that is formed on the lower surface of the oscillator substrate and that is located within an orthographic projection of the center portion on the lower surface. The connecting portions are disposed to connect the oscillators to the connecting frames. Each of the oscillators is connected to the corresponding one of the connecting frames through at least a corresponding one of the connecting portions. A thickness of each of the connecting portions is equal to a thickness of the oscillator substrate.

According to a second aspect of the disclosure, the method for making the oscillators, includes the steps of:
forming the above-mentioned oscillator master board, the oscillator master board including the oscillators; and
separating each of the oscillators from the at least a corresponding one of the connecting portions to obtain the oscillators that are independent and separated from each other.

According to a third aspect of the disclosure, the oscillators are made by the above-mentioned method.

According to a fourth aspect of the disclosure, the method for making the oscillator master board includes the steps of:
a) providing a starting substrate which is made of piezoelectric materials, the starting substrate defining
   an outer frame region,
   connecting frame regions which are located within the outer frame region and which are connected to the outer frame region, the connecting frame regions extending along a first direction and being spaced apart from each other along a second direction, and
   oscillator regions which are arranged in array, each of the oscillator regions being located adjacent to a corresponding one of the connecting frame regions;
b) forming back electrodes on a back surface of the starting substrate by vapor deposition, the back electrodes being respectively on positions corresponding to the oscillator regions;
c) thinning the staring substrate from a front surface of the starting substrate which is opposite to the back surface so as to form the starting substrate into a thinned substrate including a thinned outer frame region obtained from the outer frame region, thinned connecting frame regions obtained from the connecting frame regions, and thinned oscillator regions obtained from the oscillator regions;
d) forming a first mask over the thinned substrate and etching the thinned substrate through the first mask so as to form the thinned oscillator regions into etched semi-finished products, thereby obtaining an intermediate structure including intermediate substrates and intermediate connecting portions, wherein an exposed portion of the thinned substrate, which is exposed from the first mask, is etched to have a first thickness, and each of the etched semi-finished products includes a corresponding one of the intermediate substrates and at least a corresponding one of the intermediate connecting portions which extends in one-piece form from a side edge of the corresponding one of the intermediate substrates to be connected to a corresponding one of the thinned connecting frame regions;
e) forming a second mask including frame-like mask portions respectively on peripheries of the intermediate substrates of the intermediate structure, and etching an exposed portion of the intermediate structure which is exposed from the second mask, a reduced thickness of the exposed portion of the intermediate structure being not greater than the first thickness
   such that the intermediate substrates are formed into oscillator substrates and top frames respectively formed on upper surfaces of the oscillator substrates, the back electrodes being respectively located on lower surfaces of the oscillator substrates,
   such that the thinned connecting frame regions, which are exposed from the second mask, are formed into connecting frames, and
   such that the intermediate connecting portions are formed into connecting portions which connect the oscillator substrates with the connecting frames; and
f) depositing top electrode units and back extending electrodes, each of the top electrode units being deposited on a center portion of a respective one of the upper surfaces of the oscillator substrates, each of the back extending electrodes extending from a respective one of the back electrodes through a side edge of a respective one of the oscillator substrates to the respective one of the upper surfaces of the oscillator substrates, so as to obtain the oscillator master board.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a top view illustrating an oscillator according to an embodiment of the disclosure.

FIG. 2 is a cross-sectional view taken along line II-II of FIG. 1.

FIG. 3 is a top view illustrating an oscillator master board according to an embodiment of the disclosure.

FIG. 4 is a schematic structural view illustrating steps a) to d) of a method for making the oscillator master board.

FIG. 5 is a schematic structural view illustrating step d) of the method for making the oscillator master board.

FIG. 6 is a schematic structural view illustrating step e) of the method for making the oscillator master board.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

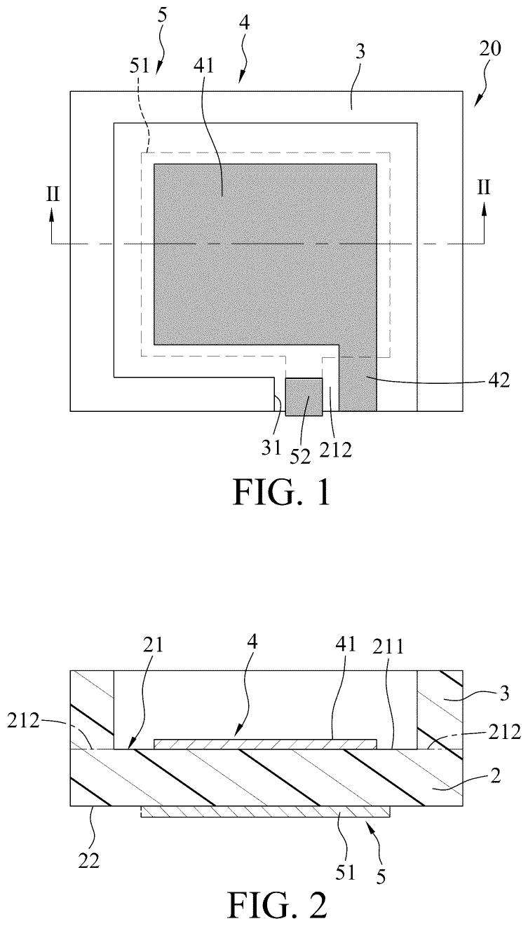

FIGS. 1 and 2 illustrate an oscillator 20 according to an embodiment of the disclosure. FIG. 2 is a cross-sectional view of the oscillator 20 taken along line II-II of FIG. 1. Referring to FIGS. 1 and 2, the oscillator 20 includes an oscillator substrate 2, a top frame 3, a top electrode unit 4 and a back electrode unit 5. As illustrated by the embodiment of the disclosure, the oscillator substrate 2 is made of quartz. In some embodiments, oscillator 20 is a crystal oscillator.

The oscillator substrate 2 includes an upper surface 21 and a lower surface 22 that are opposite to each other. The upper surface 21 defines a center portion 211 and an outer edge portion 212 that surrounds the center portion 211.

The top frame 3 is made of a material same as that of the oscillator substrate 2, extends upwardly in one-piece form from the outer edge portion 212 of the oscillator substrate 2, and includes a notch 31 that exposes the outer edge portion 212 of the upper surface 21 of the oscillator substrate 2.

The top electrode unit 4 includes a top electrode 41 that is formed on the center portion 211 of the upper surface 21 of the oscillator substrate 2, and a top extending electrode 42 that extends from the top electrode 41 through the notch 31.

The back electrode unit 5 includes a back electrode 51 that is formed on the lower surface 22 of the oscillator substrate 2, and a back extending electrode 52 that extends from the back electrode 51 through a side edge of the oscillator substrate 2 to the outer edge portion 212 of the upper surface 21 of the oscillator substrate 2 where the top extending electrode 42 is located. To be specific, the back electrode 51 is located within an orthographic projection of the center portion 211 on the lower surface 22.

In the embodiment of the disclosure, a thickness of the oscillator substrate 2 is not greater than 30 μm so that the oscillator 20 may serve as a high-frequency oscillator suitable for generating an oscillation frequency greater than 90 MHz.

In some embodiments, the thickness of the oscillator substrate 2 is not greater than 20 μm.

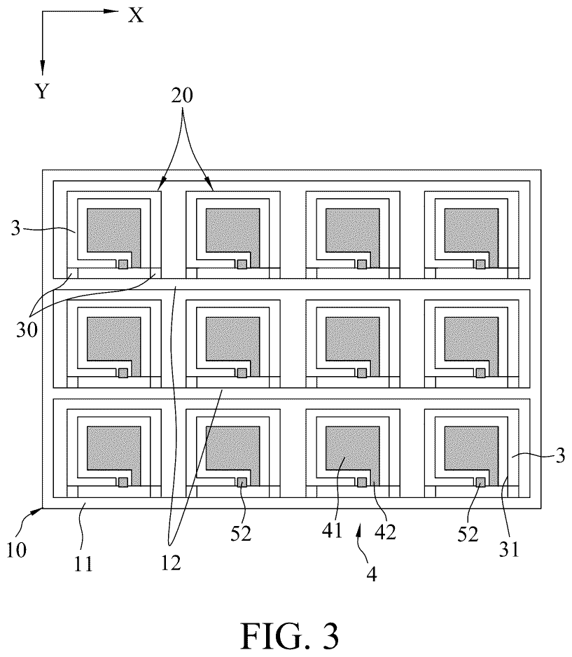

Referring to FIGS. 1 and 3, an oscillator master board may be first formed with a plurality of the oscillators 20 as shown in FIG. 3. Thereafter, the oscillator master board is processed to obtain the oscillators 20 that are independent and separated from each other.

Specifically, the oscillator master board includes a frame 10, the oscillators 20 and connecting portions 30.

The frame 10 includes an outer frame 11 and connecting frames 12 which are disposed within the outer frame 11 and which are connected to the outer frame 11. The connecting frames 12 extend along a first direction (X) and are spaced apart from each other along a second direction (Y) that intersects the first direction (X). In some embodiments, the second direction (Y) is perpendicular to the first direction (X). The number of the connecting frames 12 may be two as shown in FIG. 3, or more than two.

The oscillators 20 are spaced apart from each other, and are disposed adjacent to a corresponding one of the connecting frames 12. Each of the oscillators 20 has a structure as described above.

The connecting portions 30 are disposed to connect the oscillators 20 and the connecting frames 12. The oscillator substrate 2, the connecting portions 30 and the top frame 3 are made of the same material including quartz. The oscillator substrate 2 of each of the oscillators 20 is connected to the corresponding one of the connecting frames 12 through at least a corresponding one of the connecting portions 30. To be specific, the oscillator substrate 2 of each of the oscillators 20 is integrally connected as one piece with the at least a corresponding one of the connecting portions 30 and the corresponding one of the connecting frames 12. A thickness of each of the connecting portions 30 and the thickness of the oscillator substrate 2 are identical and are each not greater than 30 μm.

In the embodiment, each of the oscillators 20 is connected to the corresponding one of the connecting frames 12 through two corresponding ones of the connecting portions 30 that are separately disposed on and extend from the same side edge of the oscillator substrate 2, and that are connected to the oscillator substrate 2. In other words, each of the oscillators 20 is connected to the corresponding one of the connecting frames 12 through the two corresponding ones of the connecting portions 30 that are separately disposed on and extend from the same side edge of the corresponding one of the connecting frames 12, and that are connected to the corresponding one of the connecting frames 12. In addition, for each of the oscillators 20, the two corresponding ones of the connecting portions 30 are located on the same side of the notch 31 on the oscillator substrate 2. However, in actual implementation, as long as the connecting portions 30 are used to connect the oscillators 20 and the connecting frames 12, quantities and distribution pattern of the connecting portions 30, the oscillators 20 and the connecting frames 12 are not limited.

In a process for separating each of oscillators 20 from the oscillator master board, since each of the connecting portions 30 is extremely thin (having thickness not greater than 30 μm) and is liable to be broken by knocking, cutting, etc., each of the oscillators 20 is easily separated from the connecting portions 30. Therefore, during separation of the oscillators 20 from the oscillator master board, damage to the oscillators 20 may be reduced so as to effectively enhance production yield.

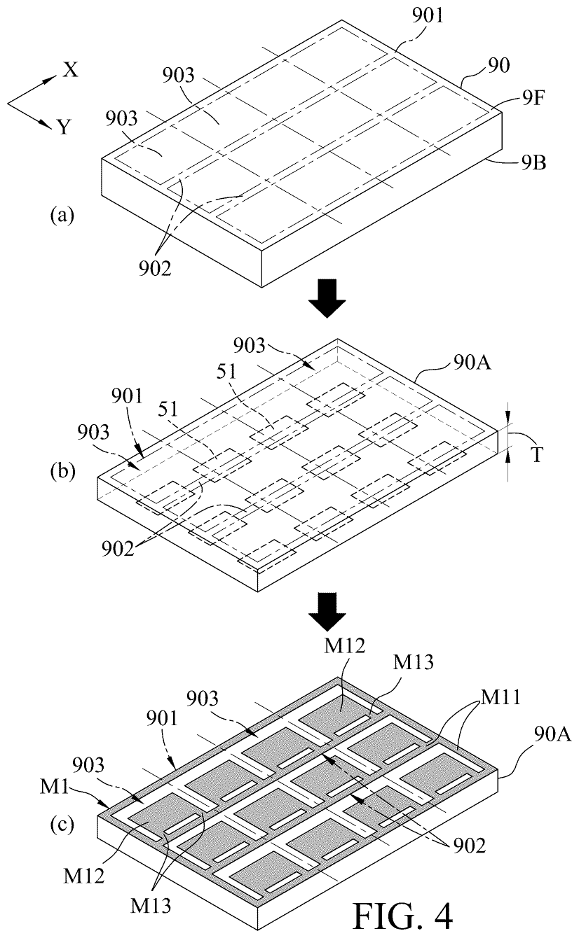

Referring to FIGS. 4 to 6, a method for making the above-mentioned oscillator master board includes steps a) to f) and is described as follows.

Referring to FIG. 4, step a) is first performed to provide a starting substrate 90 that has a relatively great thickness and that is made of piezoelectric materials. The starting substrate 90 defines an outer frame region 901, connecting frame regions 902 and oscillator regions 903 as shown in (a) of FIG. 4. The connecting frame regions 902 are located within the outer frame region 901 and are connected to the outer frame region 901. The connecting frame regions 902 extend along the first direction (X) and are spaced apart from each other along the second direction (Y). The oscillator regions 903 are arranged in array and are located adjacent to a corresponding one of the connecting frame regions 902. In the subsequent manufacturing processes, the oscillator regions 903 are formed into the oscillators 20 and the connecting portions 30. A surface area of the oscillator substrate 2 of each of the oscillators 20 is smaller than a surface area of a corresponding one of the oscillator regions 903.

Then, step b) is performed to form the back electrodes 51 (thereafter serving as the back electrodes 51 of the oscillators 20) on a back surface 9B of the starting substrate 90 by vapor deposition. The back electrodes 51 are respectively on positions corresponding to the oscillator regions 903.

Then, step c) is performed to dispose the starting substrate 90 on a temporary substrate (not shown in the figure) with the back electrodes 51 facing the temporary substrate, and to thin the starting substrate 90 from a front surface 9F of the starting substrate 90 that is opposite to the back electrodes 51 of the back surface 9B so as to form the starting substrate 90 into a thinned substrate 90A with a thickness (T). The thinned substrate 90A includes a thinned outer frame region 901 obtained from the outer frame region 901, thinned connecting frame regions 902 obtained from the connecting frame regions 902, and thinned oscillator regions 903 obtained from the oscillator regions 903, as shown in (b) of FIG. 4.

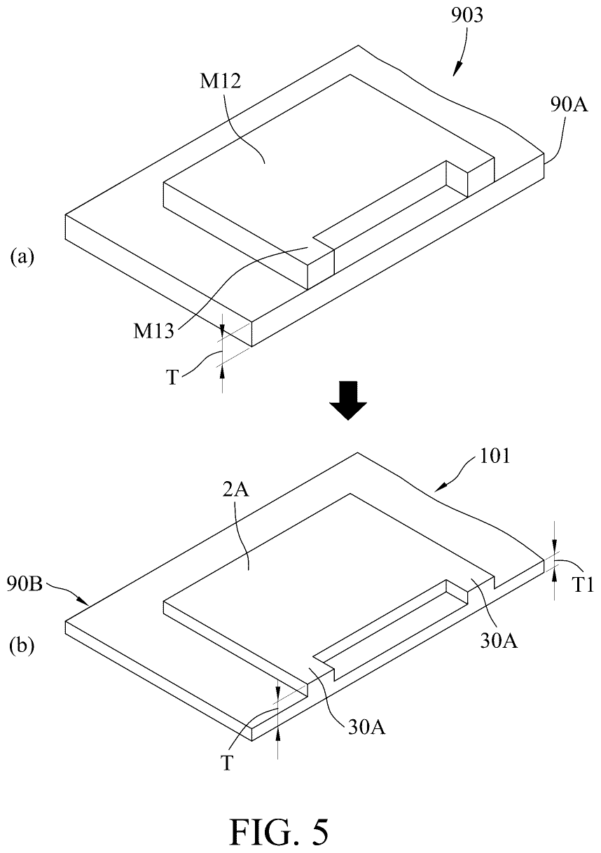

Then, step d), which includes a first photolithography process and a first etching process, is performed on the thinned substrate 90A. To be specific, in the first photolithography process, a first mask M1 is formed over the thinned substrate 90A (see (c) of FIG. 4). In the first etching process, the thinned substrate 90A is etched through the first mask M1 so as to form the thinned oscillator regions 903 (one of which is shown in (a) of FIG. 5) into etched semi-finished products 101 (one of which is shown in (b) of FIG. 5).

The first photolithography process involves forming a first photoresist layer (not shown in the figure) on a surface of the thinned substrate 90A that is opposite to the back electrodes 51, exposing the first photoresist layer by using a first photomask (not shown in the figure), and then developing the first photoresist layer to form the first mask M1 as shown in (c) of FIG. 4. The first mask M1 includes a frame mask portion M11, substrate mask portions M12 and connecting mask portions M13. The frame mask portion M11 covers the thinned outer frame region 901 and the thinned connecting frame regions 902. Each of the substrate mask portions M12 partially covers a corresponding one of the thinned oscillator regions 903, and has dimensions and a contour that match those of the oscillator substrate 2 of a corresponding one of the oscillators 20 shown in FIGS. 1 and 2. The connecting mask portions M13 have dimensions and are in positions corresponding to the connecting portions 30 (see FIG. 3). Each two of the connecting mask portions M13 extend from a corresponding one of the substrate mask portions M12 and are connected to the frame mask portion M11. In (a) of FIG. 5, one of the substrate mask portions M12 and two corresponding ones of the connecting mask portions M13 are shown.

Then, in the first etching process, the surface of the thinned substrate 90A, which is opposite to the back electrodes 51, is etched by utilizing the first mask M1 as a mask. An exposed portion of the thinned substrate 90A, which is exposed from the first mask M1, is etched to have a first thickness T1. The thinned outer frame region 901 and the thinned connecting frame regions 902 shown in (c) of FIG. 4 are protected by the frame mask portion M11 and are not etched. The thinned oscillator regions 903 are formed into the etched semi-finished products 101. After the etching process, an intermediate structure 90B is obtained and includes the thinned outer frame region 901, the thinned connecting frame regions 902, intermediate substrates 2A (each of which has a contour corresponding to a contour of a corresponding one of the substrate mask portions M12, and one of which is shown in (b) of FIG. 5) and intermediate connecting portions 30A (each of which has a contour corresponding to a contour of a corresponding one of the connecting mask portions M13, and two of which are shown in (b) of FIG. 5). Each of the etched semi-finished products 101 includes a corresponding one of the intermediate substrates 2A, and two corresponding ones of the intermediate connecting portions 30A which extend in one-piece form from a side edge of the corresponding one of the intermediate substrates 2A to be connected to a corresponding one of the thinned connecting frame regions 902. The thinned outer frame region 901, the thinned connecting frame regions 902, and portions of the thinned oscillator regions 903 (for forming the intermediate substrates 2A and the intermediate connecting portions 30A) are covered by the first mask pattern M1, and thus have a thickness (T) which is the same as the thickness (T) of the thinned substrate 90A. However, the exposed portion of the thinned substrate 90A, which is not covered by the first mask M1 (especially the portions of the thinned oscillator regions 903 exposed from the substrate mask portions M12 and the connecting mask portions M13), is etched, and thus after etching, a thickness of the exposed portion of the substrate 90A is reduced to the first thickness T1.

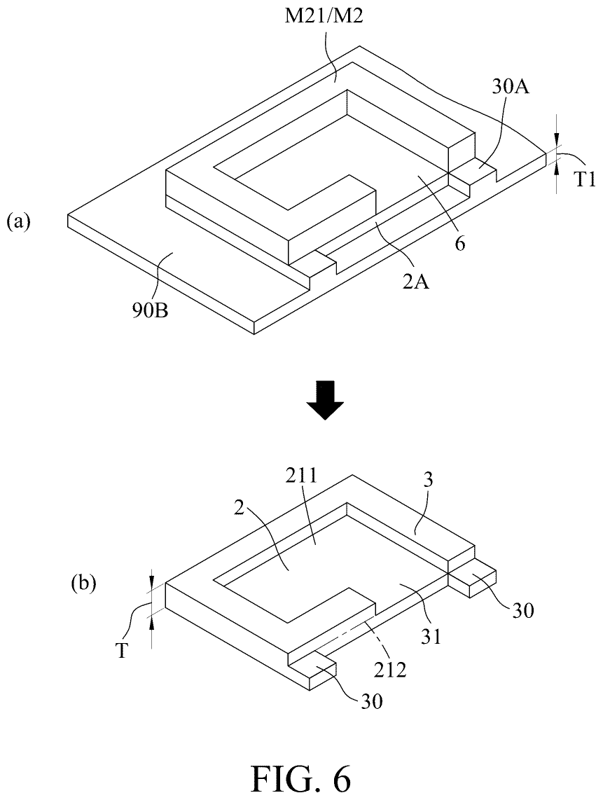

FIG. 6 is a schematic perspective view of a structure obtained subsequent to that shown in (b) of FIG. 5. Referring to FIG. 6, step e), which includes a second photolithography process and a second etching process, is performed on the intermediate structure 90B. To be specific, in the second photolithography process, a second mask M2 is formed over the intermediate structure 90B (see (a) of FIG. 6). In the second etching process, the intermediate structure 90B is etched through the second mask M2. The intermediate substrates 2A are formed into the oscillator substrates 2 (one of which is shown in (b) of FIG. 6) and the top frames 3 (one of which is shown in (b) of FIG. 6) of the oscillators 20 (see FIG. 3). The intermediate connecting portions 30A are formed into the connecting portions 30 shown in FIG. 3. By performing the aforesaid steps a) to e), each of the oscillator regions 903 shown in (a) of FIG. 4 is formed into one of the oscillator substrates 2 and a corresponding one of the top frames 3.

In the second photolithography process, a second photoresist layer (not shown in the figure) is formed on a surface of the intermediate structure 90B that is opposite to the back electrodes 51, and is exposed through a second photomask (not shown in the figure), and the second photoresist layer is developed to form the second mask M2. The second mask M2 includes frame-like mask portions M21 (one of which is shown in (a) of FIG. 6). Each of the frame-like mask portions M21 is formed on a surface of the corresponding one of the intermediate substrates 2A that is opposite to a corresponding one of the back electrodes 51 (not shown in (a) of FIG. 6). Each of the frame-like mask portions M21 has a contour, a dimension and a position that correspond to those of the corresponding one of the top frames 3 of the oscillators 20 shown in FIG. 3. Then, an exposed portion of the intermediate structure 90B, which is not covered by the second mask M2, is etched by utilizing the second mask M2 as a mask. A reduced thickness of the exposed portion of the intermediate structure 90B is not greater than the first thickness T1. In this embodiment, the reduced thickness of the exposed portion of the intermediate structure 90B is the first thickness T1. Accordingly, portions of the intermediate substrates 2A that respectively are covered by the frame-like mask portions M21 are not etched. Therefore, after etching, the portions of the intermediate substrates 2A are formed into the top frames 3. Other portions of the intermediate substrates 2A, which are not covered by the frame-like mask portions M21, are etched away by a thickness that is equal to the first thickness T1. As such, the intermediate substrates 2A are formed into the oscillator substrates 2 and the top frames 3, and the top frames 3 are respectively formed on the outer edge portions 212 of the upper surfaces 21 of the oscillator substrates 2. The back electrodes 51 are respectively located on the lower surfaces 22 of the oscillator substrates 2. It should be noted that, the frame-like mask portions M21 respectively have cutouts 6 (one of which is shown in (a) of FIG. 6) such that the top frames 3 includes the notches 31 which respectively expose the upper surfaces 21 of the oscillator substrates 2. In other words, the second mask M2 including the frame-like mask patterns M21, which are respectively located on peripheries of the intermediate substrates 2A of the intermediate structure 90B, is formed, and the exposed portion of the intermediate structure 90B, which is exposed from the second mask M2, is recessed. Furthermore, the thinned outer frame region 901, the thinned connecting frame regions 902 and the intermediate connecting portions 30A that are not covered by the second mask M2 are also etched away by the thickness that is equal to the first thickness T1. Therefore, as shown in FIG. 3, the thinned outer frame region 901 is formed into the outer frame 11, the thinned connecting frame regions 902 are formed into the connecting frames 12, and the intermediate connecting portions 30A are formed into the connecting portions 30 that connect the oscillator substrates 2 with the connecting frames 12.

The starting substrate 90 with an original thickness of 60 μm is taken as an instance for illustration. After step c), the starting substrate 90 (see (a) of FIG. 4) is thinned to obtain the thinned substrate 90A (see (b) of FIG. 4) with a thickness of 40 μm. After step d), the exposed portion of the thinned substrate 90A (see (a) of FIG. 5) is etched to have a thickness of 25 μm (the first thickness T1), while a non-exposed portion of the thinned substrate 90A (which is formed to be the intermediate substrates 2A and intermediate connecting portions 30A in the intermediate structure 90B) remains to have the thickness of 40 μm (the thickness (T)). After step e), 25 μm (the first thickness T1) of the exposed portion of the intermediate structure 90B (see (a) of FIG. 6) is removed. Therefore, after etching, the center portion 211 of each of the oscillator substrates 2 (see (b) of FIG. 6) thereby obtained has a thickness of 15 μm (which is obtained by 40 μm minus 25 μm). However, a total thickness of the outer edge portion 212 of each of the oscillator substrates 2 and the corresponding one of the top frames 3 is maintained to be 40 μm. In addition, each of the connecting portions 30, which connects a corresponding one of the oscillator substrates 2 and the corresponding one of the connecting frames 12 (see also FIG. 3), has a thickness of only 15 μm so that each of the connecting portions 30 is extremely susceptible to damage without affecting the corresponding one of the oscillator substrates 2 that is connected thereto.

Finally, step f) is performed to deposit the top electrode units 4 and the back extending electrodes 52 of the oscillators 20 by utilizing a third photoresist layer and a third photomask (not shown in the figure). Each of the top electrode units 4 is deposited on a surface of the center portion 211 of a respective one of the upper surfaces 21 of the oscillator substrates 2, and each of the back extending electrodes 52 extends from a respective one of the back electrodes 51 through a side edge of the respective one of the oscillator substrates 2 to the respective one of the upper surfaces 21 of the oscillator substrates 2, so as to obtain the oscillator master board.

The aforementioned first photomask, second photomask and third photomask may be made of magnetic materials so as to maintain better alignment during exposure by magnetically fixing the same.

It should be noted that after step e), each of the connecting frames 12 and each of the connecting portions 30 is extremely thin. In order to prevent the connecting frames 12 from breakage during subsequent manufacturing processes, metals may also be deposited on the connecting frames 12 to enhance strength of the connecting frames 12 during deposition of the top electrode units 4 in step f).

In summary, in the disclosure, by utilizing multiple etching processes and structural design of the oscillator master board, the oscillator master board may be formed with the oscillators 20. The center portion 211 of each of the oscillators 20 is extremely thin and is adapted to generate oscillations. The top frame 3 and the outer edge portion 212 of each of the oscillators 20 cooperate to have a greater thickness to be held and clamped in the manufacturing processes. Therefore, each of the oscillators 20 can be separated from the two corresponding one of the connecting portions 30 to obtain the oscillators 20 that are independent and separated from each other. In addition, each of the oscillators 20 of the oscillator master board is connected to a corresponding adjacent one of the connecting frames 12 through the two corresponding ones of the connecting portions 30 that are extremely thin. Therefore, the connecting portions 30 may be susceptible to separation from the corresponding one of the oscillators 20 without damaging the corresponding one of the oscillators 20 during separation so as to effectively improve and maintain yields of the oscillators 20 finally obtained, thereby indeed achieving purposes of the disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An oscillator master board, comprising:
a frame which includes an outer frame and connecting frames that are disposed within said outer frame and that are connected to said outer frame, said connecting frames extending along a first direction and being spaced apart from each other along a second direction that intersects the first direction;
oscillators which are spaced apart from each other, each of said oscillators being disposed adjacent to a corresponding one of said connecting frames and including
an oscillator substrate which has an upper surface and a lower surface that are opposite to each other, said upper surface having a center portion and an outer edge portion that surrounds said center portion,
a top frame which is formed on said outer edge portion of said oscillator substrate,
a top electrode unit which includes a top electrode that is formed on said center portion, and
a back electrode unit which includes a back electrode that is formed on said lower surface of said oscillator substrate and that is located within an orthographic projection of said center portion on said lower surface; and
connecting portions which are disposed to connect said oscillators to said connecting frames, each of said oscillators being connected to said corresponding one of said connecting frames through at least a corresponding one of said connecting portions, a thickness of each of said connecting portions being equal to a thickness of said oscillator substrate.

2. The oscillator master board as claimed in claim 1, wherein:
said oscillator substrate, said connecting portions and said top frame are each made of a material including quartz;
said oscillator substrate of each of said oscillators is integrally connected as one piece with said at least a corresponding one of said connecting portions and said corresponding one of said connecting frames; and
said thickness of each of said connecting portions and said thickness of said oscillator substrate are each not greater than 30 μm.

3. The oscillator master board as claimed in claim 1, wherein each of said oscillators is connected to said corresponding one of said connecting frames through two corresponding ones of said connecting portions that extend from a same side edge of said corresponding one of said connecting frames and are connected to said corresponding one of said connecting frames.

4. The oscillator master board as claimed in claim 1, wherein:
said top frame has a notch which exposes said outer edge portion of said upper surface of said oscillator substrate;
said top electrode unit further includes a top extending electrode that extends from said top electrode through said notch; and
said back electrode unit further includes a back extending electrode that extends from said back electrode through a side edge of said oscillator substrate to said outer edge portion of said upper surface where said top extending electrode is located.

5. The oscillator master board as claimed in claim 1, wherein each of said oscillators is connected to said corresponding one of said connecting frames through two corresponding ones of said connecting portions that are separately disposed on a same side edge of said oscillator substrate.

6. A method for making oscillators, comprising the steps of:
forming the oscillator master board as claimed in claim 1, the oscillator master board including the oscillators; and
separating each of the oscillators from the at least a corresponding one of the connecting portions to obtain the oscillators that are independent and separated from each other.

7. Oscillators, which are made by the method as claimed in claim 6.

8. The oscillators as claimed in claim 7, wherein said thickness of said oscillator substrate is not greater than 30 μm.

9. A method for making an oscillator master board, comprising the following steps:
a) providing a starting substrate which is made of piezoelectric materials,
the starting substrate defining
an outer frame region,
connecting frame regions which are located within the outer frame region and which are connected to the outer frame region, the connecting frame regions extending along a first direction and being spaced apart from each other along a second direction, and
oscillator regions which are arranged in array, each of the oscillator regions being located adjacent to a corresponding one of the connecting frame regions;
b) forming back electrodes on a back surface of the starting substrate by vapor deposition, the back electrodes being respectively on positions corresponding to the oscillator regions;
c) thinning the staring substrate from a front surface of the starting substrate which is opposite to the back surface so as to form the starting substrate into a thinned substrate including a thinned outer frame region obtained from the outer frame region, thinned connecting frame regions obtained from the connecting frame regions, and thinned oscillator regions obtained from the oscillator regions;
d) forming a first mask over the thinned substrate and etching the thinned substrate through the first mask so as to form the thinned oscillator regions into etched semi-finished products, thereby obtaining an intermediate structure including intermediate substrates and intermediate connecting portions, wherein an exposed portion of the thinned substrate, which is exposed from the first mask, is etched to have a first thickness, and each of the etched semi-finished products includes a corresponding one of the intermediate substrates and at least a corresponding one of the intermediate connecting portions which extends in one-piece form from a side edge of the corresponding one of the intermediate substrates to be connected to a corresponding one of the thinned connecting frame regions;
e) forming a second mask including frame-like mask portions respectively on peripheries of the intermediate substrates of the intermediate structure, and etching an exposed portion of the intermediate structure which is exposed from the second mask, a reduced thickness of the exposed portion of the intermediate structure being not greater than the first thickness
such that the intermediate substrates are formed into oscillator substrates and top frames respectively formed on upper surfaces of the oscillator substrates, the back electrodes being respectively located on lower surfaces of the oscillator substrates,
such that the thinned connecting frame regions, which are exposed from the second mask, are formed into connecting frames, and
such that the intermediate connecting portions are formed into connecting portions which connect the oscillator substrates with the connecting frames; and
f) depositing top electrode units and back extending electrodes, each of the top electrode units being deposited on a center portion of a respective one of the upper surfaces of the oscillator substrates, each of the back extending electrodes extending from a respective one of the back electrodes through a side edge of a respective one of the oscillator substrates to the respective one of the upper surfaces of the oscillator substrates, so as to obtain the oscillator master board.

10. The method as claimed in claim 9, wherein, in step e), the frame-like mask portions respectively have cutouts such that the top frames include notches which respectively expose the upper surfaces of the oscillator substrates, the reduced thickness of the exposed portion of the intermediate structure being equal to the first thickness.

11. The method as claimed in claim 9, wherein:
during patterning the thinned substrate in step d), the thinned outer frame region and the thinned connecting frame regions are covered by the first mask; and
the intermediate structure further includes the thinned outer frame region and the thinned connecting frame regions.

12. The method as claimed in claim 9, wherein, in step e),
the thinned outer frame region is exposed from the second mask and is formed into an outer frame.
